(19) United States
(12) Patent Application Publication
(10) Pub. No.: US 2014/0021038 A1
(43) Pub. Date: Jan. 23, 2014

(54) SPUTTERING TARGET, METHOD FOR MANUFACTURING THE SAME, AND METHOD FOR MANUFACTURING THIN FILM TRANSISTOR

(71) Applicants: Takatsugu Kusumi, Osaka-shi (JP); Yohsuke Kanzaki, Osaka-shi (JP)

(72) Inventors: Takatsugu Kusumi, Osaka-shi (JP); Yohsuke Kanzaki, Osaka-shi (JP)

(73) Assignee: SHARP KABUSHIKI KAISHA, Osaka-shi, Osaka (JP)

(21) Appl. No.: 14/001,986

(22) PCT Filed: Feb. 23, 2012
(86) PCT No.: PCT/JP2012/054370

§ 371 Date: Sep. 27, 2013

(30) Foreign Application Priority Data
Mar. 1, 2011 (JP) 2011044085

(51) Int. Cl. H01L 21/02

(52) U.S. Cl. CPC H01L 21/02365
USPC 204/192.25; 204/298.12; 204/298.13; 156/268

(57) ABSTRACT

An object is to provide a sputtering target capable of obtaining a film having favorable characteristics.

A sputtering target (100) is configured of a plurality of target materials (10) made of IGZO, a backing plate (20) made of Cu or the like, and a bonding material (30) made of In or the like. The plurality of target materials (10) are bonded with the backing plate (20) via the bonding material 30. A groove (40) having a length (L2), a width (W3) and a depth (D1) is provided on the surface of each target material (10). This groove (40) is provided parallel to a joint (15) of the mutually adjacent target materials (10) in the vicinity of the joint (15) (position with a distance (W2) from the joint (15)). The width (W3) of the groove (40) and the distance (W2) between the joint (15) and the groove (40) are sufficiently smaller than the length (L1) of each of upper and lower sides of the target material (10).

### TECHNICAL FIELD

The present invention relates to a sputtering target, a method for manufacturing the same, and a method for manufacturing a thin-film transistor, and especially relates to a split sputtering target provided with a plurality of target materials, a method for manufacturing the same, and a method for manufacturing a thin-film transistor using the sputtering target.

### BACKGROUND ART

A thin-film transistor (TFT) with an oxide semiconductor used in a channel layer has hitherto been receiving attention. An oxide semiconductor film has been used for a liquid crystal display device and the like due to its high mobility as well as transparency of visible light. As the oxide semiconductor film, for example, one made of InGaZnOₓ (hereinafter, referred to as “IGZO”) is known which is mainly composed of indium (In), gallium (Ga), zinc (Zn) and oxygen (O).

A sputtering method is known as one of methods for forming such an oxide semiconductor film. A sputtering target used in this sputtering method generally has a configuration formed by bonding a target material made of a material for a thin film to be formed and a support material made of a material excellent in electric conductivity and thermal conductivity, such as copper (Cu), via a bonding material made of In or the like.

In a magnetron sputtering method as one of the sputtering methods, sputtering is performed with a magnet arranged on the rear surface of a sputtering target. A film can be formed at high speed by the magnetron sputtering method. For this reason, the magnetron sputtering method is broadly used for formation of the oxide semiconductor film.

In recent years, a display panel for a liquid crystal display device or the like is increasing in size. With this increase, the target material is required to also increase in size. However, it is generally difficult to form a large-sized target material. There has thus been proposed a split sputtering target in which a plurality of target materials are provided in a tabular shape on a support material. With such a configuration, it is possible to deal with the increase in size of the sputtering target by increasing the number of target materials.

The split sputtering target is generally provided with a slight gap in a joint between mutually adjacent target materials in order to prevent cracking and the like of the target materials. Films with properties different from each other are formed respectively in a position corresponding to the joint of the target materials and a position other than the position corresponding to the joint. That is, there has hitherto been a problem in that a characteristic of the TFT formed in the position corresponding to the joint deteriorates as compared to a characteristic of the TFT formed in the position other than the position corresponding to the joint.

Associated with the present invention, Patent Document 1 discloses a sputtering target in which a protective material made of either a material resistant to sputtering or the same material as one for the target material is provided in a joint between the target materials. With such a configuration, it is possible to prevent a support material from being sputtered in the joint and being mixed into a thin film.

Further, Patent Document 2 discloses a sputtering target in which a large number of edges are provided on the surface of a target material. With such a configuration, it is possible to perform sputtering at high speed.

Moreover, Patent Document 3 discloses a sputtering target in which grooves are provided on both sides of a region apt to be eroded in a target material. With such a configuration, it is possible to enhance the usage efficiency of the target material.

### PRIOR ART DOCUMENTS

### Patent Documents

[Patent Document 1] Japanese Patent Application Laid-Open No. H10-121232
[Patent Document 2] Japanese Patent Application Laid-Open No. H6-287750
[Patent Document 3] Japanese Patent Application Laid-Open No. H11-193457

### SUMMARY OF THE INVENTION

### Problems to be Solved by the Invention

However, in the sputtering targets described in above Patent Documents 1 to 3, it is not possible to prevent a change in film property which is attributable to electric-field concentration in a joint 15.

Accordingly, it is an object of the present invention to provide a sputtering target capable of obtaining a film having favorable characteristics.

Further, it is another object of the present invention to provide a method for manufacturing a sputtering target capable of obtaining a film having favorable characteristics.

Furthermore, it is still another object of the present invention to provide a method for manufacturing a thin-film transistor using a sputtering target capable of obtaining a semiconductor film having favorable characteristics.

### Solution to the Problems

A first aspect of the present invention is directed to a sputtering target, comprising:

a plurality of target materials made of an identical material;

a support material that supports the plurality of target materials; and

a bonding material that bonds the plurality of target materials and the support material, wherein

a surface of at least one of the mutually adjacent target materials is provided with a groove that splits the surface into two or more regions.

In a second aspect of the present invention, based on the first aspect of the present invention, wherein each target material is made of a semiconductor.

In a third aspect of the present invention, based on the second aspect of the present invention, wherein said semiconductor is an oxide semiconductor.

In a fourth aspect of the present invention, based on the third aspect of the present invention, wherein the oxide semiconductor mainly contains indium, gallium, zinc and oxygen.

In a fifth aspect of the present invention, based on the third aspect of the present invention, wherein the oxide semiconductor contains at least one of indium, gallium, zinc, copper, silicon, tin, aluminum, calcium, germanium and lead.

In a sixth aspect of the present invention, based on the second aspect of the present invention, wherein the groove is provided parallel to the joint between the mutually adjacent target materials.

In a seventh aspect of the present invention, based on the sixth aspect of the present invention, wherein the groove is provided in the vicinity of the joint.

In a eighth aspect of the present invention, based on the seventh aspect of the present invention, wherein, corresponding to the joint, at least one groove is provided on each of one surface and the other surface of the mutually adjacent target materials.

In a ninth aspect of the present invention, based on the eighth aspect of the present invention, wherein, corresponding to the joint, a plurality of grooves are provided on each of one surface and the other surface of the mutually adjacent target materials.

In a tenth aspect of the present invention, based on the seventh aspect of the present invention, wherein, corresponding to the joint, one groove is provided on one surface of the mutually adjacent target materials.

In an eleventh aspect of the present invention, based on the second aspect of the present invention, wherein a depth of the groove is one-half or larger of a thickness of the target material provided with the groove, and smaller than the thickness of the target material provided with the groove

In a twelfth aspect of the present invention, based on the second aspect of the present invention, wherein edge portions of each target material which correspond to the groove and the joint are chamfered.

In a thirteenth aspect of the present invention, based on the second aspect of the present invention, wherein

the support material is formed in a tabular shape, and

each target material is formed in a tabular shape.

In a fourteenth aspect of the present invention, based on the second aspect of the present invention, wherein

the support material is formed in a cylindrical shape or in a columnar shape, and

each target material is formed in the cylindrical shape.

A fifteenth aspect of the present invention is directed to a method for manufacturing a thin-film transistor, comprising a step of:

forming a channel layer by sputtering the sputtering target according to any one of the second to fourteenth aspects of the present invention.

A sixteenth aspect of the present invention is directed to a method for manufacturing a sputtering target having a plurality of target materials made of an identical material, a support material that supports the plurality of target materials, and a bonding material that joins the plurality of target materials and the support material, the method comprising a step of:

forming a groove on the surface of at least one of the mutually adjacent target materials, the groove splitting the surface into two or more regions.

### Effects of the Invention

According to the first aspect of the present invention, the surface of at least one of the mutually adjacent target materials is provided with the groove along one side of the one target material. This alleviates electric-field concentration in the joint between the mutually adjacent target materials. Hence it is possible to obtain a film having favorable characteristics.

According to the second aspect of the present invention, it is possible to obtain a semiconductor film having favorable characteristics.

According to the third aspect of the present invention, it is possible to obtain an oxide semiconductor film having favorable characteristics.

According to the fourth aspect of the present invention, it is possible to obtain an IGZO semiconductor film having favorable characteristics.

According to the fifth aspect of the present invention, it is possible to obtain a so-called IGZO-based oxide semiconductor film having favorable characteristics.

According to the sixth aspect of the present invention, the groove along the joint is provided, and hence it is possible to exert a similar effect to that of the second aspect of the present invention.

According to the seventh aspect of the present invention, the groove is provided in the vicinity of the joint. This can further alleviate the electric-field concentration in this joint. Hence it is possible to obtain a semiconductor film having still more favorable characteristics.

According to the eighth aspect of the present invention, corresponding to the joint, at least one groove is provided on each of one surface and the other surface of the mutually adjacent target materials forming this joint. This can further alleviate the electric-field concentration in the joint. Hence it is possible to obtain a semiconductor film having still more favorable characteristics.

According to the ninth aspect of the present invention, corresponding to the joint, a plurality of grooves are provided on each of one surface and the other surface of the mutually adjacent target materials forming this joint. This further alleviates the electric-field concentration in the joint, and also alleviates the electric-field concentration in the groove. Hence it is possible to obtain a semiconductor film having still more favorable characteristics.

According to the tenth aspect of the present invention, corresponding to the joint, one groove is provided on one surface of the mutually adjacent target materials forming this joint. This can reduce the number of grooves, thereby to reduce cost for forming the grooves. Further, the strength of the target material can be held in a sufficient degree.

According to the eleventh aspect of the present invention, the surface of the target material is provided with a groove whose depth is one-half or larger of the thickness of the target material, and smaller than the thickness of the target material. This extends the life of the groove. Hence it is possible to prevent deterioration in characteristics of the semiconductor film to be formed even when sputtering of the target material proceeds.

According to the twelfth aspect of the present invention, the edge portions of the target material which correspond to the groove and the joint are chamfered. This further alleviates the electric-field concentration in the joint, and also alleviates the electric-field concentration in the groove. Hence it is possible to obtain a semiconductor film having still more favorable characteristics.

According to the thirteenth aspect of the present invention, in the sputtering target with the target material being formed in the tabular shape, it is possible to exert a similar effect to that of the second aspect of the present invention.

According to the fourteenth aspect of the present invention, in the sputtering target with the target material being formed in the cylindrical shape, it is possible to exert a similar effect to that of the second aspect of the present invention.

According to the fifteenth aspect of the present invention, it is possible to obtain a thin-film transistor provided with a channel layer having favorable characteristics.

According to the sixteenth aspect of the present invention, it is possible to obtain a sputtering target capable of obtaining a film having favorable characteristics.

### BRIEF DESCRIPTION OF THE DRAWINGS

FIG. 1 is a plan view of a sputtering target according to a first embodiment of the present invention;

FIG. 2 is a sectional view of the sputtering target taken along A-A′ line shown in FIG. 1.

FIG. 3 is a view obtained by enlarging a part of the sectional view according to FIG. 2.

FIG. 4 is a view showing another example of the first embodiment.

FIGS. 5(A) to 5(C) are views showing a method for manufacturing the sputtering target according to the first embodiment.

FIGS. 6(A) to 6(C) are views each obtained by enlarging a part of each of above FIGS. 5(A) to 5(C).

FIG. 7 is a sectional view showing a configuration of a TFT provided with a channel layer by use of the sputtering target according to the first embodiment.

FIGS. 8(A) to 8(D) are sectional views for explaining a manufacturing process for the TFT in the first embodiment.

FIGS. 9(A) and 9(B) are sectional views for explaining the manufacturing process for the TFT in the first embodiment.

FIG. 10 is a view showing a part of an active matrix substrate where the TFT shown in FIG. 7 is provided as a pixel TFT.

FIG. 11 is a view showing characteristics of the TFT provided with the channel layer by use of the sputtering target according to the first embodiment.

FIG. 12 is a plan view of a sputtering target according to a first modified example of the first embodiment.

FIG. 13 is a sectional view of the sputtering target taken along B-B′ line shown in FIG. 12;

FIG. 14 is a sectional view of a sputtering target according to a second modified example of the first embodiment.

FIG. 15 is a view obtained by enlarging a part of the sectional view according to FIG. 14.

FIG. 16 is a plan view of a sputtering target according to a third modified example of the first embodiment.

FIG. 17 is a view obtained by enlarging a part of a sectional view of the sputtering target according to a fourth modified example of the first embodiment;

FIG. 18 is a plan view of a sputtering target according to a fifth modified example of the first embodiment.

FIG. 19 is a plan view showing another mode of the fifth modified example of the first embodiment.

FIG. 20 is a plan view of a sputtering target according to a sixth modified example of the first embodiment.

FIG. 21 is a plan view showing another mode of the sixth modified example of the first embodiment.

FIG. 22 is a plan view showing another mode of the sixth modified example of the first embodiment.

FIG. 23 is a perspective view of a sputtering target according to the second embodiment of the present invention.

FIG. 24 is a sectional view of the sputtering target taken along C-C′ line shown in FIG. 23.

FIG. 25 is a view obtained by enlarging a part of the sectional view according to FIG. 24.

FIGS. 26(A) and 26(B) are views showing a method for manufacturing a sputtering target according to the second embodiment.

FIGS. 27(A) and 27(B) are views showing a method for manufacturing the sputtering target according to the second embodiment.

FIG. 28 is a plan view of a conventional sputtering target.

FIG. 29 is a sectional view of the sputtering target taken along D-D′ line shown in FIG. 28.

FIG. 30 is a view obtained by enlarging a part of the sectional view according to FIG. 29.

FIG. 31 is a sectional view showing a configuration of a TFT provided with a channel layer by use of the conventional sputtering target.

FIG. 32 is a schematic view for explaining a DC magnetron sputtering method.

FIG. 33 is a view showing characteristics of the TFT provided with the channel layer by use of the conventional sputtering target.

### MODES FOR CARRYING OUT THE INVENTION

### 0. Basic Study

Before descriptions of embodiments of the present invention, a basic study will be described which is made by the present inventors for solving the above problem.

<0.1 Configuration of Conventional Sputtering Target>

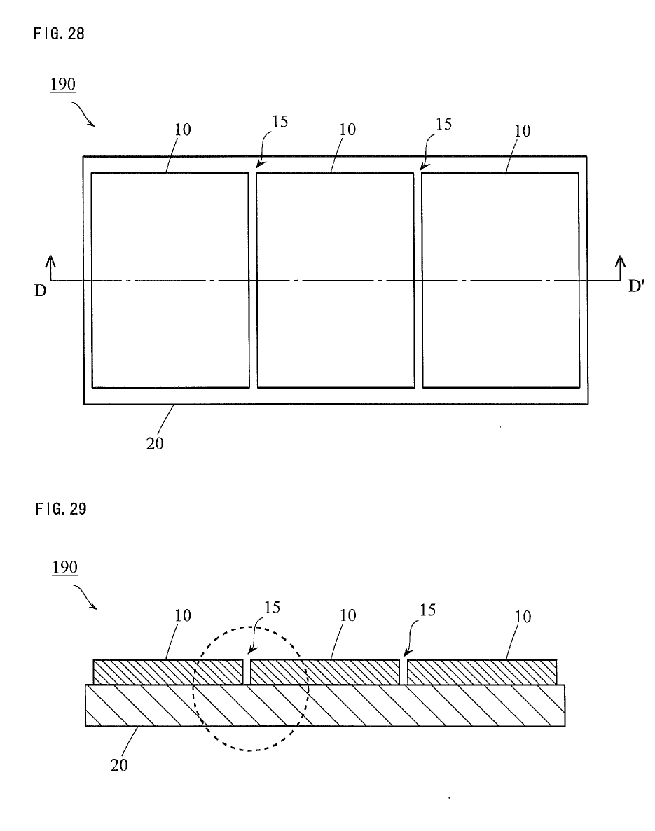

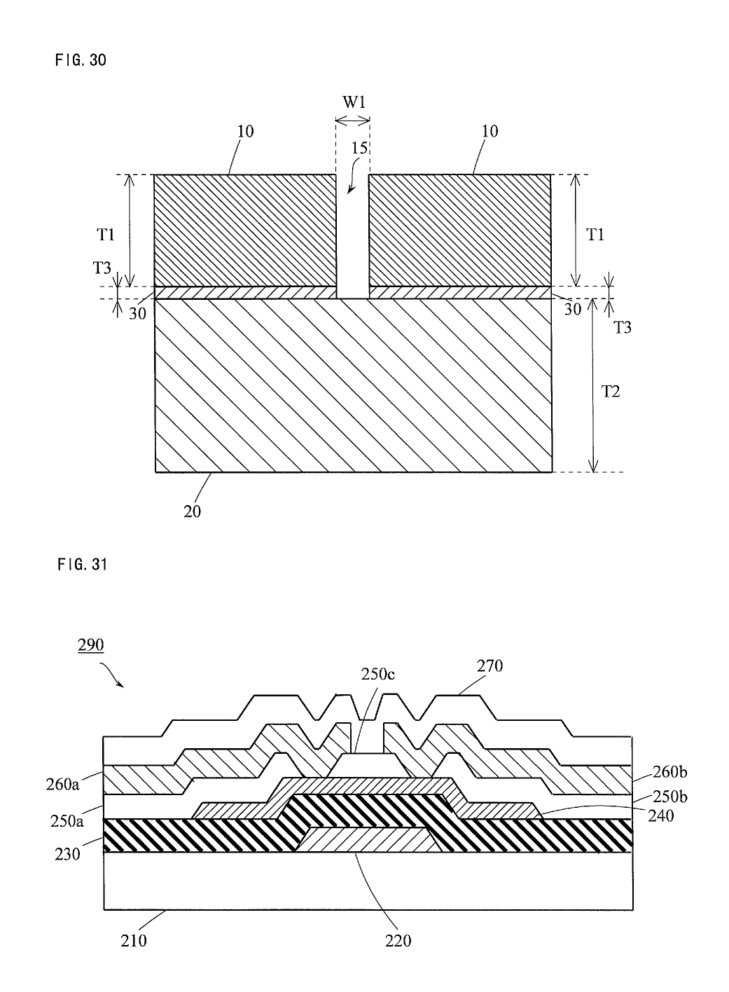

A configuration of the conventional sputtering target will be described with reference to FIGS. 28 to 30. FIG. 28 is a plan view showing a configuration of a conventional sputtering target 190. FIG. 29 is a sectional view of the sputtering target 190 taken along D-D′ line shown in FIG. 28. FIG. 30 is a view obtained by enlarging a part (portion surrounded by a broken line) of the sectional view according to FIG. 29.

The sputtering target 190 is a split sputtering target configured of a plurality of tabular target materials 10, a backing plate 20 and a bonding material 30. FIGS. 28 and 29 show an example of three of the target materials 10 being arranged alongside in the lateral direction. Each target material 10 is made of a material for a thin film to be formed. Each target material 10 in the present basic study is made of IGZO which is an oxide semiconductor mainly composed of In, Ga, Zn and O. The backing plate 20 is made of Cu or the like. The bonding material 30 is made of In or the like. The plurality of target materials 10 are bonded with the backing plate 20 via the bonding material 30. In order to prevent cracking and the like of the target materials 10, a slight gap is provided in a joint 15 between the mutually adjacent target materials 10. In this joint 15, the surface of the backing plate 20 is typically exposed as shown in FIG. 30.

<0.2 Configuration of TFT>

FIG. 31 is a sectional view showing a configuration of a TFT 290 provided with a channel layer by use of the above conventional sputtering target 190. As shown in FIG. 31, the TFT 290 is a bottom gate TFT having an etching stopper structure.

A gate electrode 220 is formed on an insulating substrate 210 made of glass or the like. The gate electrode 220 is a laminate film obtained by sequentially forming a titanium (Ti) film with a film thickness of 30 nm, an aluminum (Al) film with a film thickness of 200 nm, and a Ti film with a film thickness of 100 nm.

A gate insulating film 230 is formed on the gate electrode 220 so as to cover the gate electrode 220. The gate insulating film 230 is a laminate film obtained by sequentially forming a silicon nitride (SiNₓ) film with a film thickness of 325 nm and a silicon oxide (SiO₂) film with a film thickness of 50 nm.

A channel layer 240 made of IGZO is formed on the gate insulating film 230. A method for forming this channel layer 240 will be described later.

At the left-side top, the right-side top and the center top of the channel layer 240 in FIG. 31, etching stopper layers 250a, 250b and 250c, each made of SiO₂ and having a film thickness of 150 nm, are respectively formed.

A source electrode 260a is formed so as to cover the etching stopper layer 250a, the channel layer 240 whose surface is exposed between the etching stopper layers 250a and 250c, and the left-side end of the etching stopper layer 250c. Further, a drain electrode 260b is formed so as to cover the etching stopper layer 250b, the channel layer 240 whose surface is exposed between the etching stopper layers 250b and 250c, and the right-side end of the etching stopper layer 250c. A contact hole is formed between the etching stopper layers 250a and 250c, and this contact hole connects between the source electrode 260a and the channel layer 240. Similarly, a contact hole is formed between the etching stopper layers 250b and 250c, and this contact hole connects between the drain electrode 260b and the channel layer 240. The source electrode 260a and the drain electrode 260b are laminate films each obtained by sequentially forming a Ti-film with a film thickness of 30 nm and an Al film with a film thickness of 200 nm. It is to be noted that in place of such a laminate film, as the source electrode 260a and the drain electrode 260b, a single metal film of Ti, Al, Cu, molybdenum (Mo), tungsten (W), chromium (Cr) or the like, or an alloy film of titanium nitride (TiN), molybdenum nitride (MoN) or the like may be used, or a laminate film of these may be used.

A protective film 270 made of SiO₂ and having a film thickness of 200 nm is formed so as to cover the whole insulating substrate 210 provided with the source electrode 260a and the drain electrode 260b.

<0.3 Formation of Channel Layer>

The above channel layer 240 is formed by the magnetron sputtering method. Examples of the magnetron sputtering method include a DC (direct current) magnetron sputtering method and an RF (radio frequency) magnetron sputtering method. While either the DC magnetron sputtering method or the RF magnetron sputtering method may be used for formation of a semiconductor film made of IGZO, the following description will be given assuming that the DC magnetron sputtering is used.

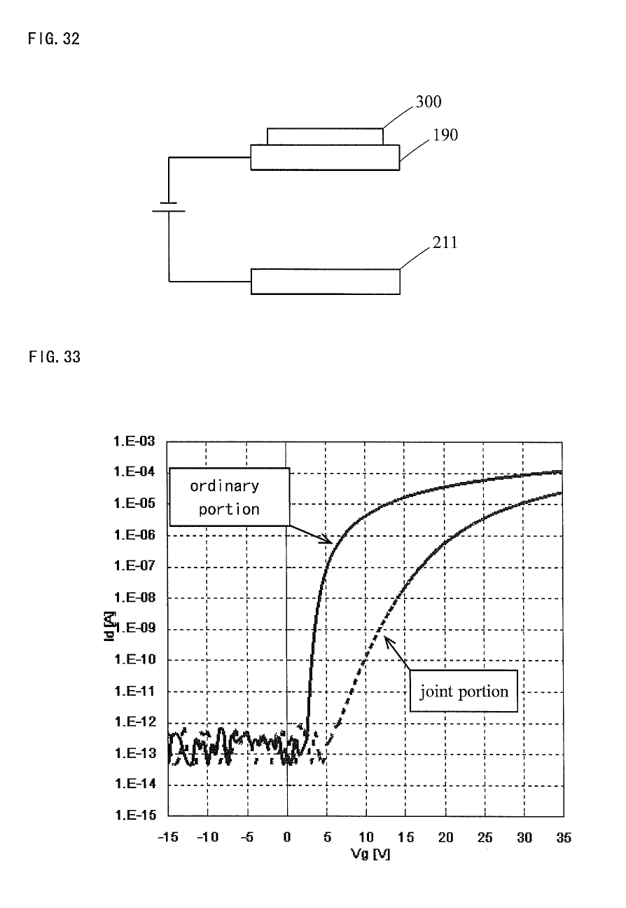

As shown in FIG. 32, in the DC magnetron sputtering method, a magnet 300 is arranged on the rear surface (surface on the backing plate 20 side) of the sputtering target 190, and a DC voltage is applied to between a substrate 211 and the sputtering target 190, on the rear surface of which the magnet 300 is arranged. The substrate 211 is the insulating substrate 210, on the surface of which the gate electrode 220 and the gate insulating film 230 are laminated. An argon (Ar) gas or the like is used as sputter gas. In addition, while a plurality of magnets 300 are typically used, one magnet 300 is used in FIG. 32 for convenience in illustration.

Upon application of the DC voltage, Ar ions are accelerated, to be collided with the surface of the target material 10 of the sputtering target 190. Thereby, atoms are sputtered from the surface of the target material 10 and reach the substrate 211. The sputtered target material 10 is deposited on the substrate 211 in this manner, to form a semiconductor film. In the magnetron sputtering method, with the magnet 300 being arranged on the rear surface of the sputtering target 190, a spiral path of electrons is bound. For this reason, high density plasma is generated in the vicinity of the target material 10. This can result in formation of the film at high speed.

<0.4 Consideration>

The present inventors performed characteristic measurement experiments on the TFT 290 provided with the channel layer 240 by use of the above conventional sputtering target 190. In the sputtering target 190 used in this experiment, a thickness T1 of each target material 10 shown in FIG. 30 is set to 6.0 mm, a thickness T2 of the backing plate 20 to 10.0 mm, a thickness T3 of the bonding material 30 to 0.3 mm, and a width W1 of the joint 15 to 0.3 mm. Further, a channel length of the TFT 290 is set to 8 μm, and a channel width thereof is set to 20 μm.

FIG. 33 is a view showing Id-Vg characteristics of the TFT 290 provided with the channel layer 240 by use of the above conventional sputtering target 190. Here, Id represents a drain current, and Vg represents a gate voltage. Further, a characteristic of the TFT 290 formed in a position other than a position corresponding to the joint 15 of the target materials 10 (hereinafter referred to as “ordinary portion”) is indicated by a solid line, and a characteristic of the TFT 290 formed in the position corresponding to the joint 15 of the target materials 10 (hereinafter referred to as “joint portion”) is indicated by a broken line.

As shown in FIG. 33, a rising edge of the Id-Vg characteristic of the TFT 290 formed in the joint portion deteriorates as compared to that of the TFT 290 formed in the ordinary portion. It has hitherto been known as a cause of this that the backing plate 20 exposed in the joint 15 of the target material 10 and the bonding material 30 exuding to the joint 15 are sputtered as impurities, which are then mixed into the semiconductor film as impurities. This leads to occurrence of deterioration in mobility of the TFT 290 formed in the joint portion, an increase in threshold voltage thereof, or the like.

However, the present inventors found that there is a cause of the deterioration in characteristic of the TFT 290 formed in the joint portion, other than that the backing plate 20 exposed in the joint 15 of the target material 10 and the bonding material 30 exuding to the joint 15 are sputtered as impurities. It is generally known that an electric field concentrates on an edge portion of a conductor. That is, the electric field concentrates in the joint 15 of the target materials 10 in the sputtering target 190. Since this concentrated electric field brings about abnormal discharge (also referred to as “arcing”) in the joint 15, the property of the semiconductor film formed in the joint portion becomes different from the property of the semiconductor film formed in the ordinary portion. That is, due to the influence of this abnormal discharge, the characteristic of the semiconductor film formed in the joint portion deteriorates. This results in occurrence of deterioration in mobility of the TFT 290 formed in the joint portion, an increase in threshold voltage thereof, or the like.

Such deterioration in characteristics of the TFT 290 cannot be resolved by adoption of the configurations of the sputtering target according to above Patent Documents 1 to 3, as described above.

Based on the above basic study, embodiments of the present invention made by the present inventors will be described with reference to the attached drawings.

### 1. First Embodiment

### 1.1 Configuration of Sputtering Target

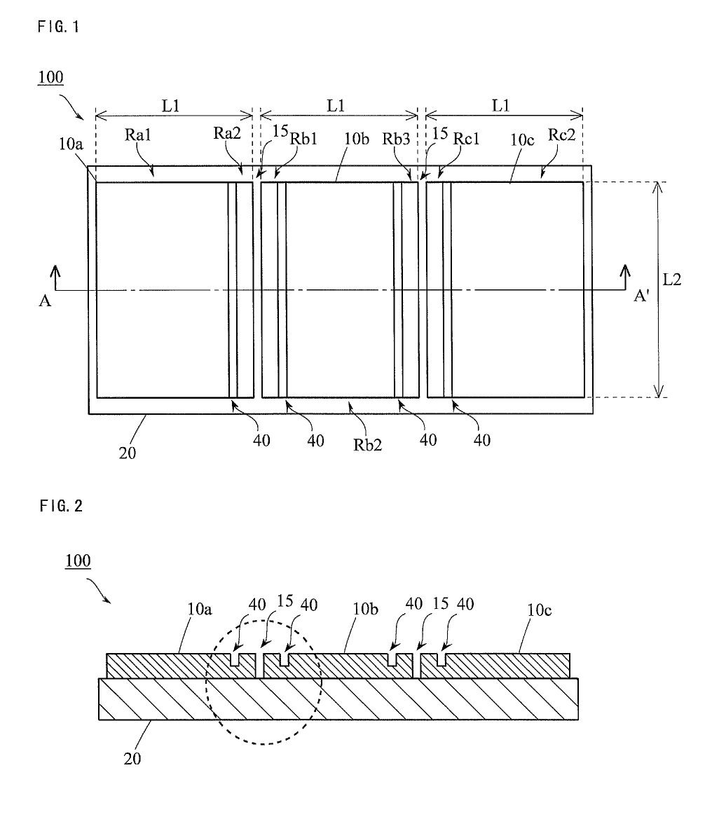

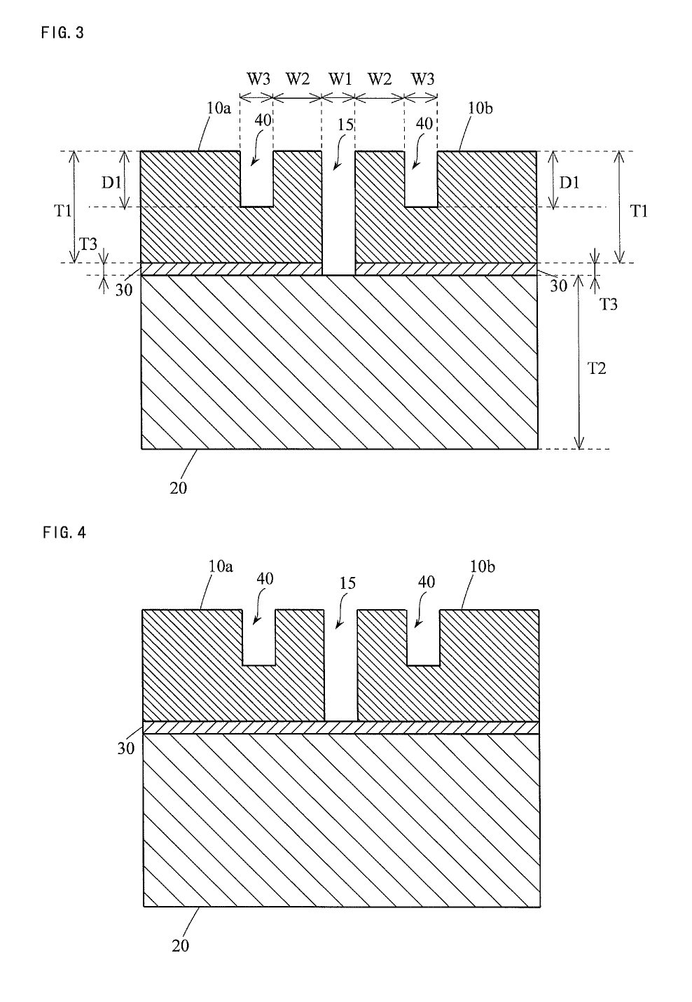

A configuration of a sputtering target according to a first embodiment of the present invention will be described with reference to FIGS. 1 to 3. FIG. 1 is a plan view showing a configuration of a sputtering target 100 according to the present embodiment. FIG. 2 is a sectional view of the sputtering target 100 taken along A-A′ line shown in FIG. 1. FIG. 3 is a view obtained by enlarging a part (portion circled by a broken line) of the sectional view according to FIG. 2.

The sputtering target 100 according to the present embodiment is a split sputtering target 100 configured of three tabular sputtering target materials 10a to 10c (hereinafter, these are each referred to as “sputtering target material 10” when not distinguished) made of the same material, the backing plate 20 as a plane-shaped support material, and the bonding material 30. Hereinafter, in the present embodiment and each of undermentioned modified examples except for a sixth modified example, in FIGS. 1 and 2 or undermentioned plan and sectional views similar thereto, the target material 10a located on the left side may be referred to as “left-side target material 10a”, the target material 10b located on the center may be referred to as “center target material 10b”, and the target material 10c located on the right side may be referred to as “right-side target material 10c”. Further, in the following description, a lateral direction and a longitudinal direction in the figure being referenced are simply referred to as “lateral direction” and “longitudinal direction”. Differently from the above conventional sputtering target 190, the sputtering target 100 according to the present embodiment is provided with a groove 40 on the surface of each target material 10. It should be noted that, while an example is shown in FIGS. 1 and 2 where three target materials 10 are arranged alongside in the lateral direction, the number of target materials 10 in the present embodiment is not restricted thereto.

Each target material 10 is bonded with the backing plate 20 via the bonding material 30. In order to prevent cracking and the like of the target materials 10, a slight gap (width W1) is provided in the joint 15 between the mutually adjacent target materials 10. The width W1 of the joint 15 is sufficiently smaller than a length L1 of the upper and lower sides of the target material 10 in FIG. 1. As shown in FIG. 3, the joint 15 is formed perpendicularly to the surface of the backing plate 20, but this is not restrictive. For example, the joint 15 may be formed in a step shape, an inclined shape, or the like.

As shown in FIG. 3, while the surface of the backing plate 20 is exposed in the joint 15 in the present embodiment, the present invention is not restricted thereto. For example, in the joint 15, the surface of the backing plate 20 may be covered by an undermentioned insulating tape or the like which is used at the time of bonding between each target material 10 and the backing plate 20. Further, in the joint 15, the surface of the backing plate 20 may be covered by the bonding material 30, as shown in FIG. 4. These are similar to each modified example and a second embodiment which will be described later.

The groove 40 is provided from the upper side to the lower side of the target material 10 in FIG. 1, parallel to both sides (right side and left side) of the target material 10 in FIG. 1. More specifically, the groove 40 having a depth D1 and the same length as a length L2 of both sides of the target material 10 is provided parallel to the joint 15 in the vicinity of the joint 15 (position with just a distance W2 from the joint 15). Here, the distance W2 between the joint 15 and the groove 40 is sufficiently smaller than the length L1 of each of the upper and lower sides of the target material 10. Further, the depth D1 of the groove 40 is smaller than the thickness T1 of the target material 10. In addition, while it is desirable that the width W1 of the joint 15 be almost the same as a width W3 of the groove 40, the present invention is not restricted thereto.

Moreover, corresponding to one joint 15, one groove 40 is provided on each of one surface and the other surface of the mutually adjacent target materials 10 forming this joint 15. That is, the grooves 40 split the surface of the left-side target material 10a into regions Ra1 and Ra2, the surface of the center target material 10b into regions Rb1, Rb2 and Rb3, and the surface of the right-side target material 10c into regions Rc1 and Rc2. More specifically, corresponding to the joint 15 formed by the left-side target material 10a and the center target material 10b, one groove 40 is provided in the left-side vicinity of this joint 15 on the surface of the left-side target material 10a, and one groove 40 is provided in the right-side vicinity of this joint 15 on the surface of the center target material 10b. Further, corresponding to the joint 15 formed by the center target material 10b and the right-side target material 10c, one groove 40 is provided in the left-side vicinity of this joint 15 on the surface of the center target material 10b, and one groove 40 is provided in the right-side vicinity of this joint 15 on the surface of the right-side target material 10c.

A material for each target material 10 is IGZO which is an oxide semiconductor mainly composed of In, Ga, Zn and O. The material for each target material 10 is not restricted thereto, but may be an oxide semiconductor (so-called IGZO-based oxide semiconductor) containing at least one of In, Ga, Zn, Cu, silicon (Si), tin (Sn), Al, calcium (Ca), germanium (Ge), and lead (Pb). Further, each target material 10 may be a semiconductor (e.g., Si) made of a substance other than oxide.

The material for the backing plate 20 is not particularly restricted, and the example thereof includes Cu and the like which is excellent in electric conductivity and thermal conductivity. The material for the bonding material 30 is not restrictive, and an example thereof includes In and the like.

### 1.2 Method for Manufacturing Sputtering Target

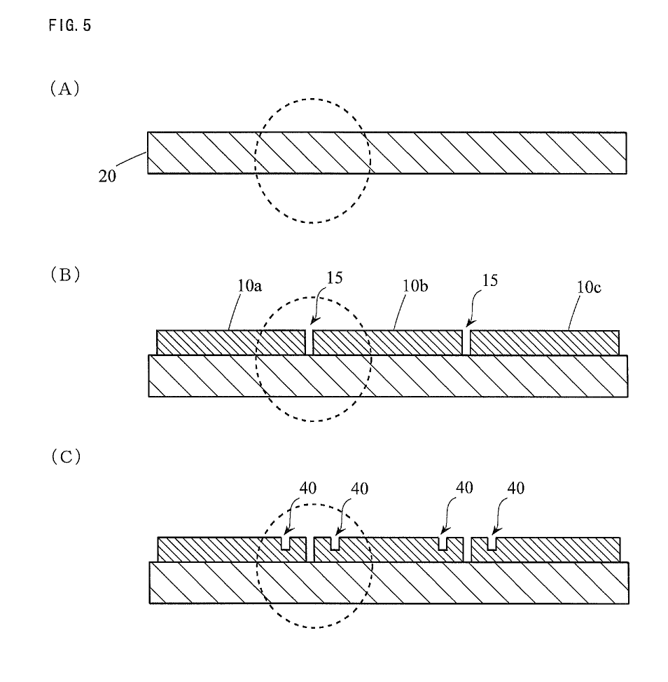

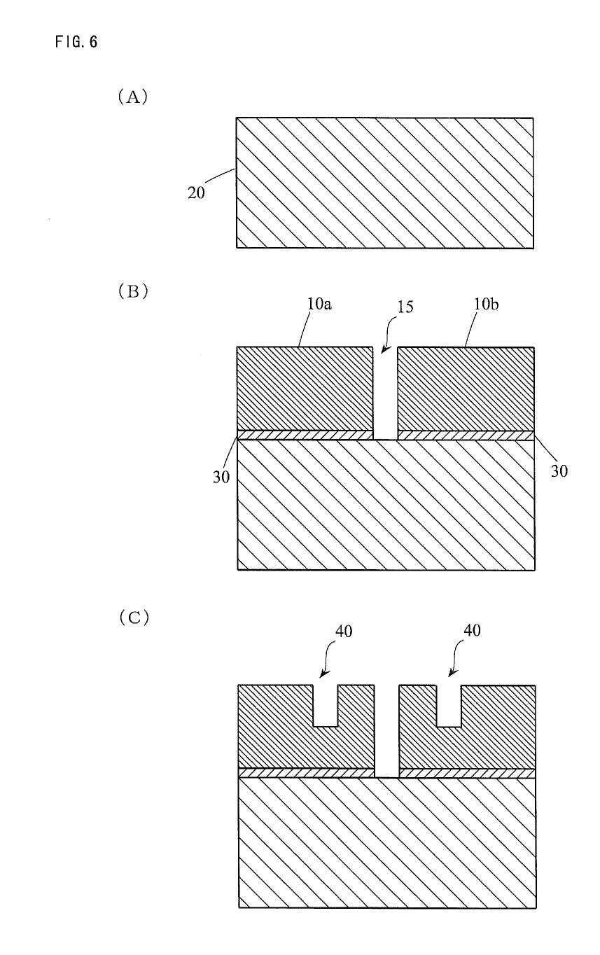

A method for manufacturing the sputtering target 100 according to the present embodiment will be described with reference to FIGS. 5(A) to 5(C) and FIGS. 6(A) to 6(C). FIGS. 5(A) to 5(C) are sectional views of the sputtering target 100 taken along A-A′ line shown in FIG. 1, for explaining the method for manufacturing the sputtering target 100 according to the present embodiment. FIGS. 6(A) to 6(C) are views each obtained by enlarging a part of each of FIGS. 5(A) to 5(C).

First, while each target material 10 made of IGZO is pressed against the tabular backing plate 20 (FIGS. 5(A), 6(A)) made of Cu or the like, the melt bonding material 30 made of In or the like is injected into between each target material 10 and the backing plate 20. It is desirable then that the target materials 10 are previously bonded to each other with a tape (e.g., insulating tape). Subsequently, this insulating tape is peeled off, and the bonding material 30 in the joint 15 is raked out. It is to be noted that this insulating tape may not be peeled off.

Subsequently, the bonding material 30 is cooled, thereby to be solidified. Hence three target materials 10 are bonded to the backing plate 20 via the bonding material (FIGS. 5(B), 6(B)). At this time, the joint 15 having the width W1 is formed. This width W1 can be accurately set by previously bonding the target materials 10 to each other by use of the insulating tape as described above.

Subsequently, using a disk grinder or the like, the groove 40 having the length L2 and the depth D1 is formed parallel to the joint 15 in a position with the distances W2 from the joint 15 on the surface of each target material 10 (FIGS. 5(C), 6(C)). At this time, the surface of the left-side target material 10a is split into regions Ra1 and Ra2, the surface of the center target material 10b is split into regions Rb1, Rb2 and Rb3, and the surface of the right-side target material 10c is split into regions Rc1 and Rc2. It should be noted that the groove 40 is formed not restrictively by grinding with a disk grinder or the like, but may be formed by lathing with a lathe or the like, or fusing with a laser or the like. Moreover, prior to bonding of the three target materials 10 to the backing plate 20, the grooves 40 may be formed on the surface of each target material 10, and thereafter, the three target materials 10 provided with the grooves 40 may be bonded to the backing plate 20.

By the above method, the sputtering target 100 according to the present embodiment is manufactured.

### 1.3 Configuration and Manufacturing Method for TFT

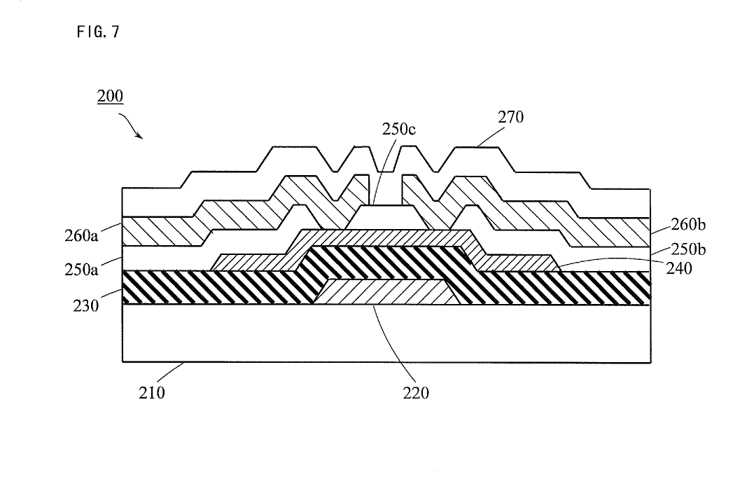

FIG. 7 is a sectional view showing a configuration of a TFT 200 provided with a channel layer by use of the sputtering target 100 according to the present embodiment. The configuration of the TFT 200 in the present embodiment is similar to the configuration of the TFT 290 in the above basic study, and a description thereof is thus omitted.

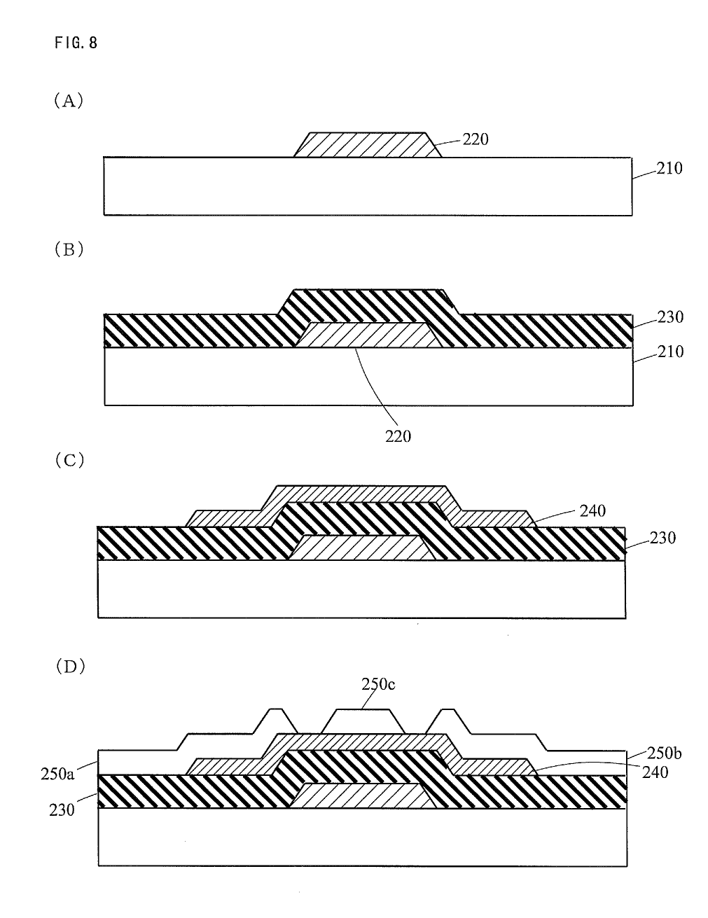

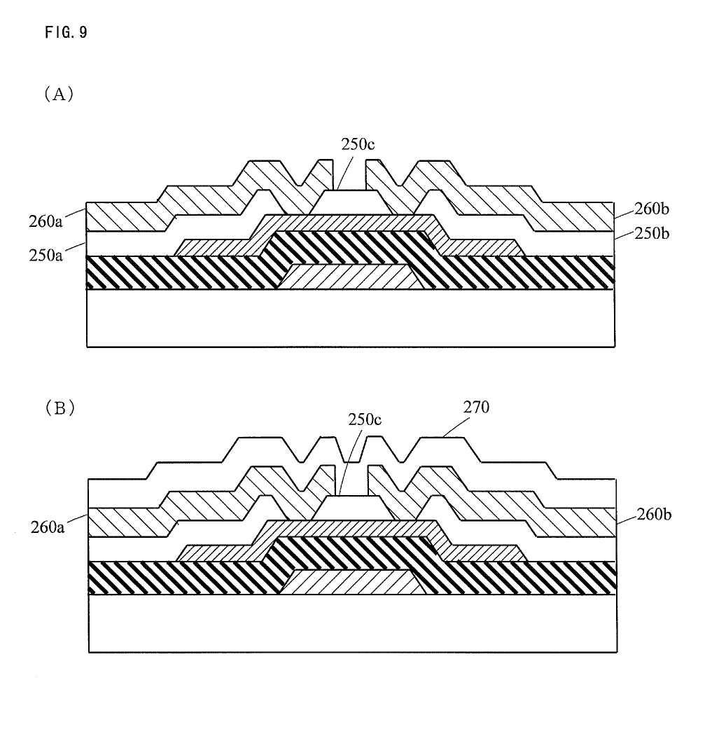

FIGS. 8(A) to 8(D), FIGS. 9(A) and 9(B) are sectional views for explaining a manufacturing process for the TFT 200 in the present embodiment. It should be noted that in FIGS. 8(A) to 8(D) and FIGS. 9(A) and 9(B), illustration of the resist pattern is omitted for convenience.

First, a laminate film, obtained by sequentially forming a Ti film with a film thickness of 30 nm, an Al film with a film thickness of 200 nm, and a Ti film with a film thickness of 100 nm, is formed on the insulating substrate 210 made of glass or the like by the sputtering method. Next, a resist pattern is formed on the center top of this laminate film by a photolithography method. Subsequently, this laminate film is etched using this resist pattern as a mask, to form the gate electrode 220 (FIG. 8(A)). Here, a dry etching method is, for example, used for the etching.

Next, after the resist pattern is peeled off, a SiNₓ film with a film thickness of 325 nm and a SiO₂ film with a film thickness of 50 nm are laminated by a plasma CVD method on the insulating substrate 210 provided with the gate electrode 220. This leads to formation of the gate insulating film 230 (FIG. 8(B)).

Subsequently, an IGZO semiconductor film is formed on the gate insulating film 230. It is to be noted that, for the formation of the IGZO semiconductor film, either the DC magnetron sputtering method or the RF magnetron sputtering method may be used. As shown in FIG. 32, for example in the DC magnetron sputtering method, the magnet 300 is arranged on the rear surface (surface on the backing plate 20 side) of the sputtering target 100 according to the present embodiment, and a DC voltage is applied to between the sputtering target 100 and the substrate 211. The substrate 211 is the insulating substrate 210, on the surface of which the gate electrode 220 and the gate insulating film 230 are laminated. An Ar gas or the like is used as sputter gas.

Upon application of the DC voltage, Ar ions are accelerated, to be collided with the surface of the target material 10 of the sputtering target 190. Thereby, atoms are sputtered from the surface of the target material 10 and reach the substrate 211. The sputtered target material 10 is deposited on the substrate 211 in this manner, to form an IGZO semiconductor film.

Subsequently, a resist pattern is formed on the center top of this IGZO semiconductor film by the photolithography method. Thereafter, this IGZO semiconductor film is etched using this resist pattern as a mask, to form the channel layer 240 (FIG. 8(C)). Here, a wet etching method is, for example, used for the etching.

Next, after the resist pattern is peeled off, an etching stopper layer made of a SiO₂ film with a film thickness of 150 nm is formed on the insulating substrate 210 provided with the channel layer 240 by means of the plasma CVD method. Subsequently, the resist patterns are formed by the photolithography method at the left-side top, the right-side top and the center top of this etching stopper layer in FIG. 8(D). The etching stopper layer 250 is etched using as this resist pattern, to form the etching stopper layers 250a, 250b and 250c respectively at the left-side top, the right-side top and the center top of the channel layer 240 (FIG. 8(D)). At this time, contact holes are formed respectively between the etching stopper layers 250a and 250c and between the etching stopper layers 250b and 250c. Here, the dry etching method is, for example, used for the etching.

Next, after the resist pattern is peeled off, a laminate film, obtained by sequentially forming a Ti film with a film thickness of 30 nm and an Al film with a film thickness of 200 nm is formed by the sputtering method so as to cover the whole insulating substrate 210. It is to be noted that in place of such a laminate film, a single metal film of Ti, Al, Cu, Mo, W, Cr or the like, or an alloy metal of TiN, MoN or the like may be formed, or a laminate film of these may be formed. Subsequently, in this laminate film, resist patterns are formed by the photolithography method in a position corresponding to the etching stopper layer 250a, the channel layer 240 whose surface is exposed between the etching stopper layers 250a and 250c, and the left-side end of the etching stopper layer 250c, and in a position corresponding to the etching stopper layer 250b, the channel layer 240 whose surface is exposed between the etching stopper layers 250b and 250c, and the right-side end of the etching stopper layer 250c. Thereafter, this laminate pattern is etched using this resist pattern as a mask. As a result, the source electrode 260a is formed so as to cover the etching stopper layer 250a, the channel layer 240 whose surface is exposed between the etching stopper layers 250a and 250c, and the left-side end of the etching stopper layer 250c, and the drain electrode 260b is formed so as to cover the etching stopper layer 250b, the channel layer 240 whose surface is exposed between the etching stopper layers 250b and 250c, and the right-side end of the etching stopper layer 250c (FIG. 9(A)). At this time, as the surface of the channel layer 240 is covered by the etching stopper layer 250c, the surface of the channel layer 240 is not etched. Here, the wet etching method is, for example, used for the etching.

Subsequently, after the resist pattern is peeled off, a protective film 270 made of SiO₂ and having a film thickness of 200 nm is formed by the plasma CVD method so as to cover the whole insulating substrate 210 (FIG. 9(B)).

The TFT 200 in the present embodiment can be manufactured by the above steps.

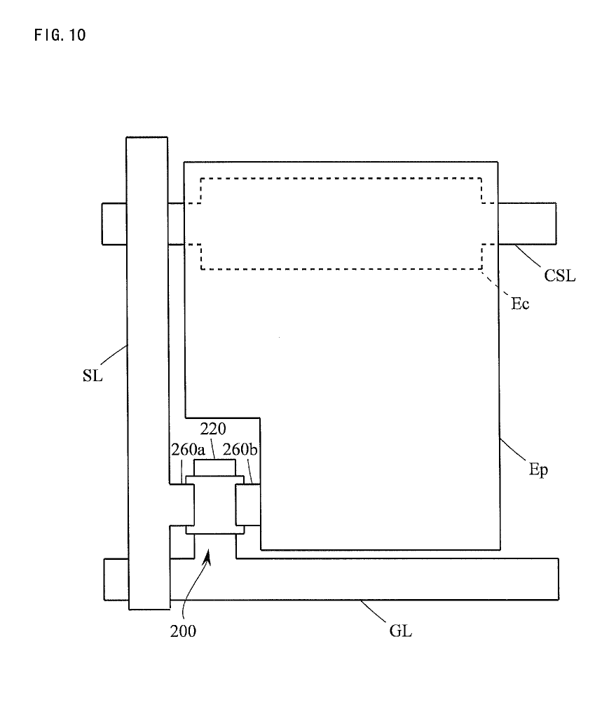

FIG. 10 is a view showing a part of an active matrix substrate of a liquid crystal display where the TFT 200 provided with the channel layer 240 by use of the sputtering target 100 according to the present embodiment is provided as a pixel TFT. This active matrix substrate is configured of a plurality of source lines SL and a plurality of gate lines GL arranged in a lattice form so as to intersect with each other, the TFT 200 provided corresponding to each intersection of the plurality of source lines SL and a plurality of gate lines GL, a pixel electrode Ep, an auxiliary capacitance electrode Ec, and an auxiliary capacitance line CSL arranged along each gate line GL, on the insulating substrate 210. The auxiliary capacitance line CSL is connected to the auxiliary capacitance electrode Ec. A space between a pixel electrode Ep and a common electrode (not shown) opposed thereto is filled with liquid crystal. A liquid crystal capacitance is formed by the pixel electrode Ep and the common electrode, and an auxiliary capacitance is formed by the pixel electrode Ep and the auxiliary capacitance line CSL.

The TFT 200 is provided corresponding to an intersection of the source line SL and the gate line GL which intersect with each other. The source electrode 260a of the TFT 200 is connected to the source line SL, the gate electrode 220 is connected to the gate line GL, and the drain electrode 260b is connected to the pixel electrode Ep. It is to be noted that, when the etching stopper layer exists as in the present embodiment, the drain electrode 260b and the pixel electrode Ep are connected with each other via a contact hole (not shown).

A plurality of source signals are applied to respectively to the plurality of source lines SL, and a plurality of gate signals are applied respectively to the plurality of gate lines GL, whereby, using as a reference a potential that is applied to the common electrode, a voltage in accordance with a pixel value of a pixel to be displayed is given to the pixel electrode via the TFT 200, and held at a pixel capacitance made up of a liquid crystal capacitance and an auxiliary capacitance. This leads to application of a voltage to the liquid crystal layer, the voltage corresponding to a potential difference between each pixel electrode and the common electrode. A light transmissibility of the liquid crystal layer is controlled by this applied voltage, to display an image.

1.4 Consideration

The present inventors performed characteristic experiments on the TFT 200 provided with the channel layer 240 by use of the sputtering target 100 according to the present embodiment. In the sputtering target 100 used in this experiment, the thickness T1 of each target material 10 shown in FIG. 3 is set to 6.0 mm, the thickness T2 of the backing plate 20 to 10.0 mm, the thickness T3 of the bonding material 30 to 0.3 mm, the depth D1 of the groove 40 to 3.0 mm, the width W1 of the joint 15 to 0.3 mm, the distance W2 between the joint 15 and the groove 40 to 10.0 mm, and the width W3 of the groove 40 to 0.3 mm. Further, a channel length of the TFT 200 is set to 8 μm, and a channel width thereof is set to 20 μm.

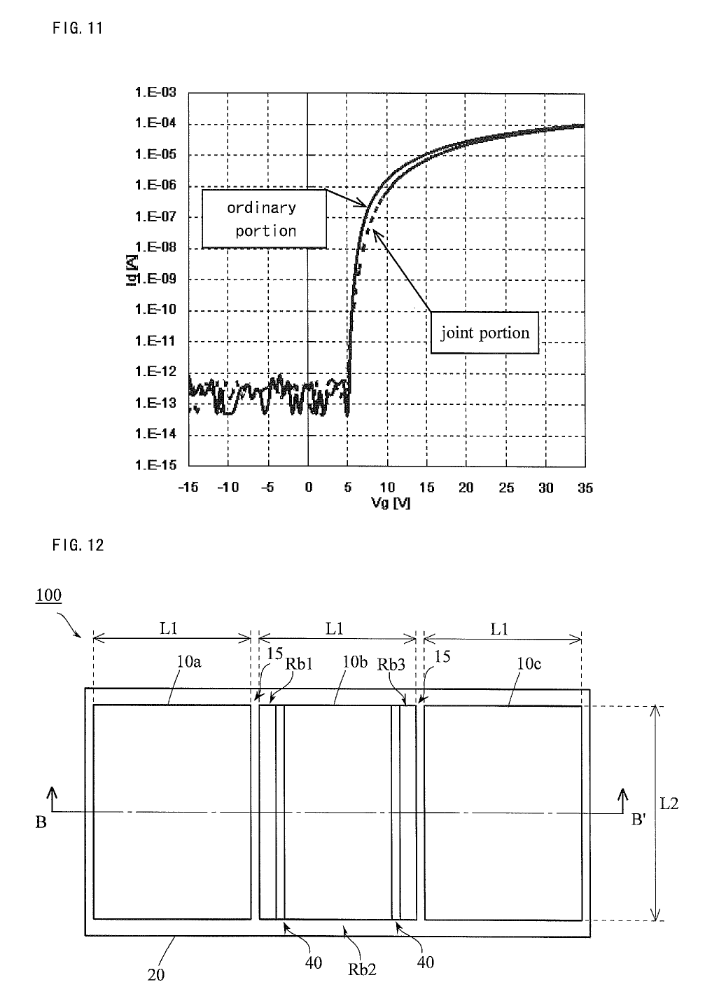

FIG. 11 is a view showing Id-Vg characteristics of the TFT 200 provided with the channel layer 240 by use of the sputtering target 100 according to the present embodiment. Here, Id represents a drain current, and Vg represents a gate voltage. Further, the characteristic of the TFT 200 formed in the ordinary portion is indicated by a solid line, and the characteristic of the TFT 200 formed in the position corresponding to the joint portion is indicated by a broken line.

There is a problem with the TFT 290 provided with the channel layer 240 by use of the above conventional sputtering target 190 in that the Id-Vg characteristic deteriorates when it is formed in the joint portion as compared to when it is formed in the ordinary portion, as described above. Meanwhile, in the TFT 200 provided with the channel layer 240 by use of the sputtering target 100 according to the present embodiment, the Id-Vg characteristic when it is formed in the ordinary portion is almost the same as the Id-Vg characteristic when it is formed in the ordinary portion.

In the sputtering target 100 according to the present embodiment, the groove 40 having a structure similar to that of the joint 15 of the target materials 10 is provided along this joint 15. This leads to dispersion of electric-field concentration, which occurs in the joint 15, to the groove 40. Therefore, the degree of the electric-field concentration, which occurs in each of the grooves 40 and the joints 15 of the sputtering target 100 according to the present embodiment, is reduced as compared to the degree of the electric-field concentration which occurs only in each of the joints 15 of the conventional sputtering target 190 not provided with the grooves 40. That is, the degree of the electric-field concentration is high to such an extent as to be observed as a characteristic defect of the TFT in the sputtering target 190, whereas the degree of the electric-field concentration is low to such a degree as not to be observed as a characteristic defect of the TFT in the sputtering target 100 according to the present embodiment. As a result, in the TFT 200 provided with the channel layer 240 by use of the sputtering target 100 according to the present embodiment, the characteristic when it is formed in the joint portion is almost the same as the characteristic when it is formed in the ordinary portion.

### 1.5. Effects

According to the present embodiment, the groove 40 is provided on the surface of the target material 10 along the joint 15. This alleviates the electric-field concentration in the joint 15. Hence it is possible to obtain a semiconductor film having favorable characteristics.

Further, according to the present embodiment, the grooves 40 are provided in the vicinities of, and on both sides of, the joint 15. This can further alleviate the electric-field concentration in the joint 15.

### 1.6 First Modified Example

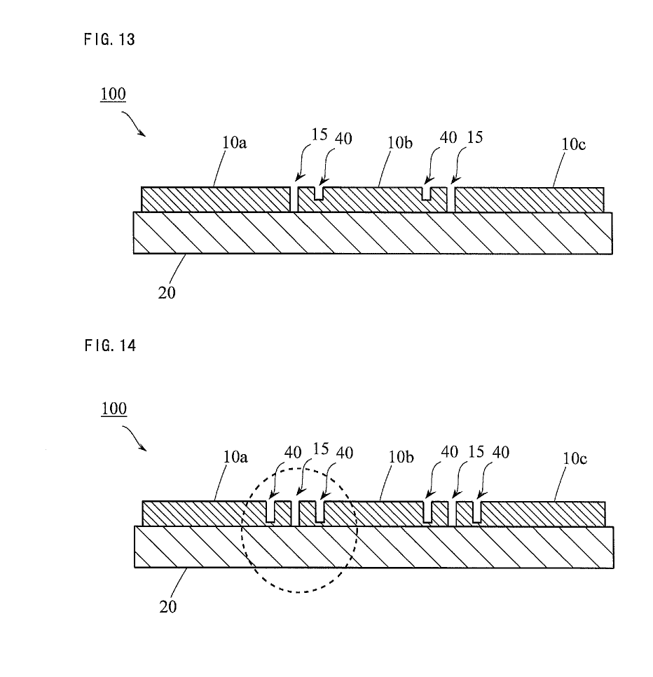

FIG. 12 is a plan view showing a configuration of the sputtering target 100 according to a first modified example of the present embodiment. FIG. 13 is a sectional view of the sputtering target 100 taken along B-B′ line shown in FIG. 12. In the sputtering target 100 according to the present modified example, one groove 40 is provided in only either one of the mutually adjacent target materials 10 forming this joint 15. In the sputtering target 100 according to the present modified example, corresponding to one joint 15, on the surface of the center target material 10b, the groove 40 having the length L2 is provided in each of the position with the distance W2 from the joint 15 formed on the left side of the center target material 10b, and the position with the distance W2 from the joint 15 formed on the right side thereto. That is, the surface of the center target material 10b is split into regions Rb1 and Rb2 by the grooves 40. On the other hand, the groove is provided neither on the surface of the left-side target material 10a nor the surface of the right-side target material 10c.

Also in the present modified example, the distance W2 between the joint 15 and the groove 40 is sufficiently smaller than the length L1 of each of the upper and lower sides of the target material 10. Further, the depth D1 of the groove 40 is smaller than the thickness T1 of the target material 10.

According to the present modified example, the number of grooves 40 is reduced as compared to the case of providing the grooves 40 on both sides of the joint 15, so as to reduce cost for forming the grooves 40. Further, the strength of the target material 10 can be held in a sufficient degree.

It should be noted that the present modified example is not restricted to the configuration where two grooves 40 are provided on the surface of the center target material 10b. For example, it may be configured that on the surface of the left-side target material 10a, the groove 40 is provided in the position with the distance W2 from the joint 15 formed on the right side of the left-side target material 10a, while on the surface of the right-side target material 10c, the groove 40 is provided in the position with the distance W2 from the joint 15 formed on the left side of the right-side target material 10c.

### 1.7 Second Modified Example

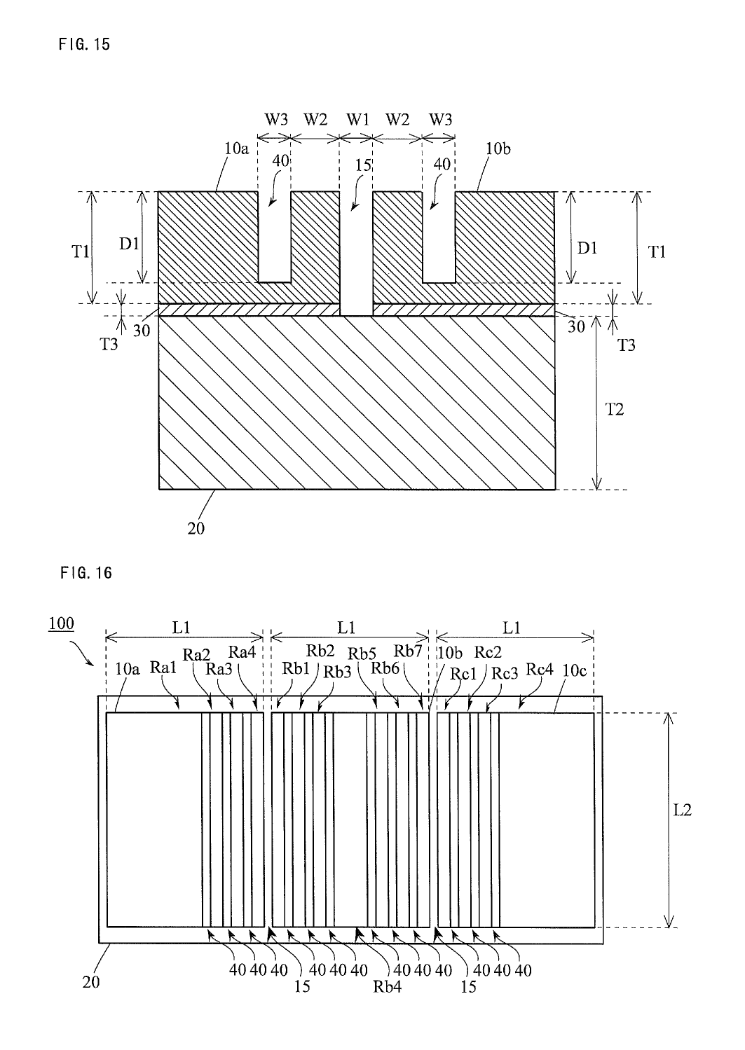

FIG. 14 is a sectional view showing a configuration of the sputtering target 100 according to a second modified example of the present embodiment. Further, FIG. 15 is a view obtained by enlarging a part (portion surrounded by a broken line) of the sectional view according to FIG. 15.

As sputtering of the target material 10 proceeds, the difference between the front surface position of the target material 10 and the bottom surface position of the groove 40 becomes shortened, and the groove 40 eventually becomes nonexistent. When the groove 40 becomes nonexistent as thus described, the electric-field concentration in the joint 15 is not alleviated, and hence the characteristic of the TFT 200 formed in the joint portion deteriorates as in the conventional case.

Hence in the sputtering target 100 according to the present modified example, the depth D1 of the groove 40 has become still larger than in the sputtering target 100 according to the aforementioned present embodiment. More specifically, the groove 40 having the depth D1 of 5.0 mm is provided in the target material 10 having the thickness T1 of 6.0 mm. It is to be noted that other parameters are similar to those in the sputtering target 100 according to the aforementioned present embodiment.

According to the present modified example, previously forming the groove 40 to be deep can extend the life of the groove 40. Hence it is possible to prevent deterioration in characteristic of the TFT 200 which is formed in the joint portion even when sputtering of the target material 10 proceeds.

### 1.8 Third Modified Examples

FIG. 16 is a plan view showing a configuration of the sputtering target 100 according to a third modified example of the present embodiment. In the sputtering target 100 according to the present modified example, corresponding to one joint 15, three grooves 40 each having the length L2 and the depth D1 are provided on each of one surface and the other surface of the mutually adjacent target materials 10 forming the joint 15. That is, the grooves 40 split the surface of the left-side target material 10a into regions Ra1, Ra2, Ra3 and Ra4, the surface of the center target material 10b into regions Rb1, Rb2, Rb3, Rb4 and Rb5, and the surface of the right-side target material 10c into regions Rc1, Rc2, Rc3 and Rc4.

More specifically, corresponding to the joint 15 formed by the left-side target material 10a and the center target material 10b, three grooves 40 each having the length L2 and the depth D1 are provided in the left-side vicinity of this joint 15 on the surface of the left-side target material 10a, and three grooves 40 each having the length L2 and the depth D1 are provided in the right-side vicinity of this joint 15 on the surface of the center target material 10b. Further, corresponding to the joint 15 formed by the center target material 10b and the right-side target material 10c, three grooves 40 are provided in the left-side vicinity of this joint 15 on the surface of the center target material 10b, and three grooves 40 are provided in the right-side vicinity of this joint 15 on the surface of the right-side target material 10c.

As thus described, in the present modified example, there increases the number of grooves 40 for dispersing the electric-field concentration which occurs in the joint 15. For this reason, the degree of the electric-field concentration which occurs in each of the joint 15 and the groove 40 is further reduced as compared to the conventional case. Accordingly, the characteristic of the TFT 200 formed in the joint portion gets still closer to the characteristic of the TFT 200 formed in the ordinary portion.

According to the present modified example, still a larger number of grooves 40 are provided. This further alleviates the electric-field concentration in the joint 15, while also alleviating the electric-field concentration in the groove 40, and hence it is possible to obtain a semiconductor film having still more favorable characteristics.

It should be noted that, while three grooves 40 are provided in each of the left-side vicinity and the right-side vicinity of each joint 15 in the present modified example, the number of grooves 40 is not restricted thereto. For example, it may be configured that two grooves 40 are provided in each of the left-side vicinity and the right-side vicinity of each joint 15. Moreover, it may be configured that four or more grooves 40 are provided in each of the left-side vicinity and the right-side vicinity of each joint 15.

### 1.9 Fourth Modified Example

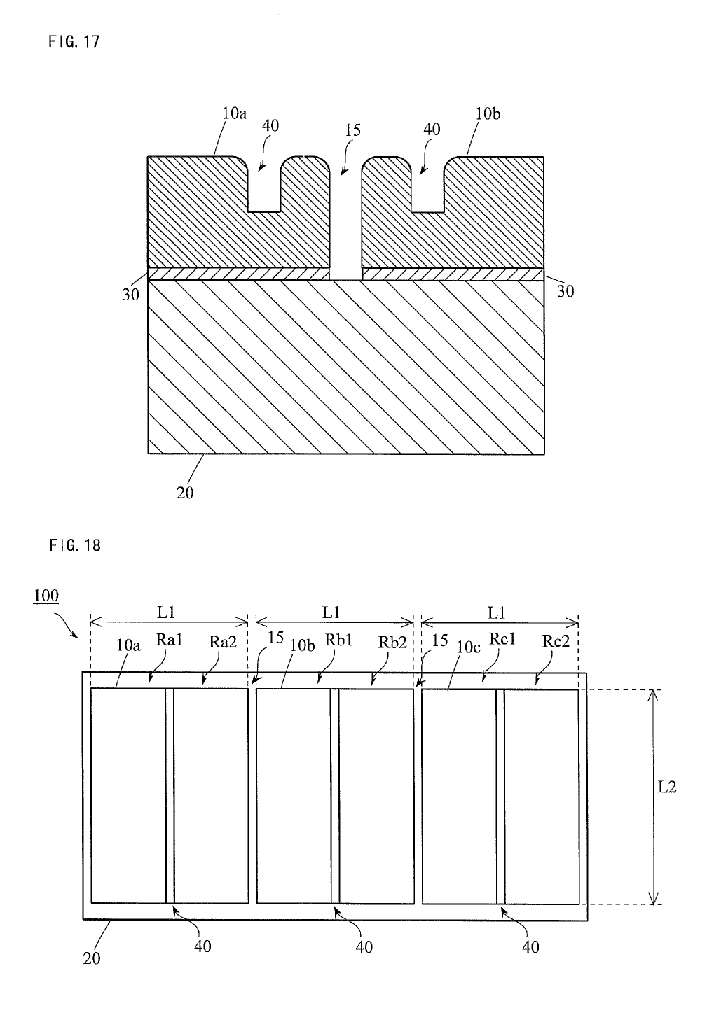

FIG. 17 is a view obtained by enlarging a part of a sectional view of the sputtering target 100 according to a fourth modified example of the present embodiment. In the sputtering target 100 according to the present modified example, the edge portions of the target material 10 which correspond to the joint 15 and the groove 40 are chamfered. For example, as shown in FIG. 17, the edge portions of the left-side target material 10a which exist in the groove 40 provided on the surface of the left-side target material 10a are chamfered, the respective edge portions of the left-side target material 10a and the center target material 10b which exist in the joint 15 formed by the left-side target material 10a and the center target material 10b are chamfered, and the edge portions of the center target material 10b which exist in the groove 40 provided on the surface of the center target material 10b are chamfered.

According to the present modified example, the electric-field concentration in the joint 15 is further alleviated, and the electric-field concentration in the groove 40 is also alleviated. Hence it is possible to obtain a semiconductor film having still more favorable characteristics.

### 1.10 Fifth Modified Example

FIG. 18 is a plan view showing a configuration of the sputtering target 100 according to a fifth modified example of the present embodiment. In the sputtering target 100 according to the present modified example, the groove 40 having the length L2 and the depth D1 and parallel to the joint 15 is provided on the lateral center of each target material 10. That is, the grooves 40 split the surface of the left-side target material 10a into regions Ra1 and Ra2, the surface of the center target material 10b into the regions Rb1 and Rb2, and the surface of the right-side target material 10c into regions Rc1 and Rc2. More specifically, one groove 40 is provided in each of the lateral center of the surface of the left-side target material 10a, the lateral center of the surface of the center target material 10b and the lateral center of the right-side target material 10c.

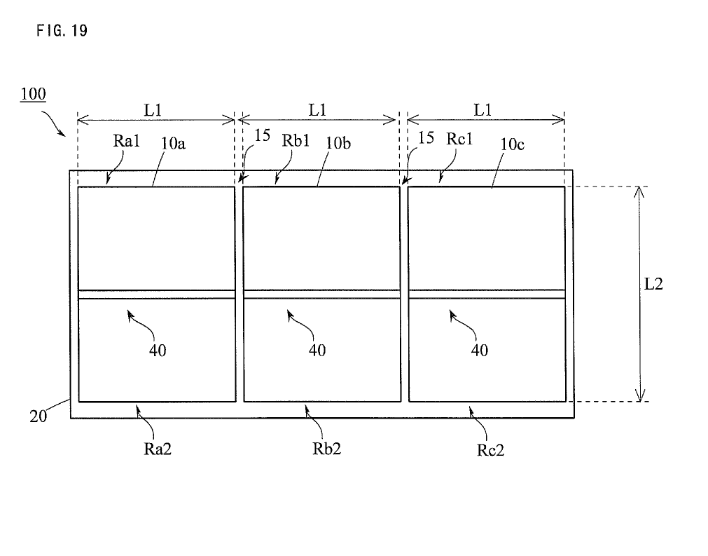

The present modified example can also alleviate the electric-field concentration in the joint 15 more than in the conventional case. Further, providing the groove 40, which has the length L1 and the depth D1 and is perpendicular to the joint 15, on the longitudinal center of the surface of each target material 10, can also alleviate the electric-field concentration in the joint 15 more than in the conventional case, as shown in FIG. 19.

### 1.11 Sixth Modified Example

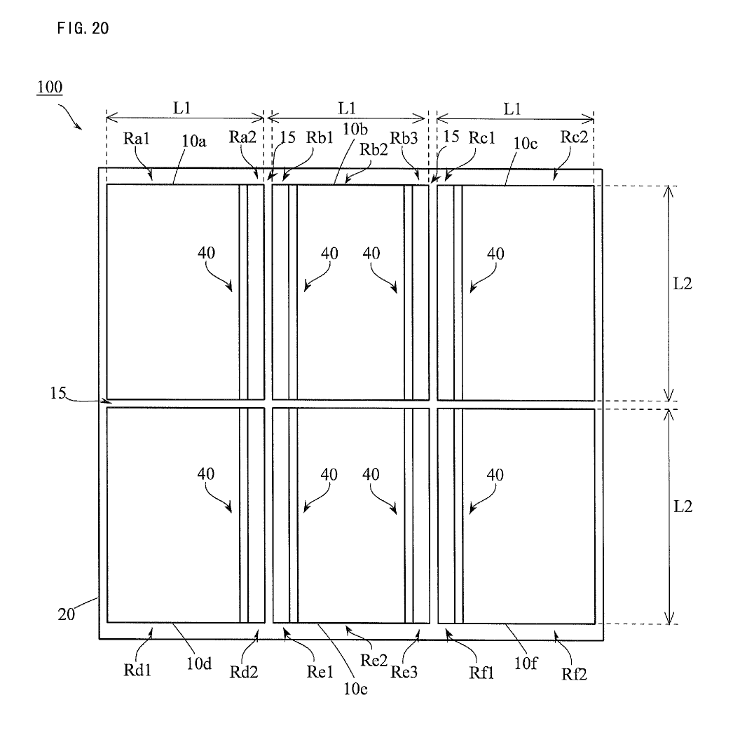

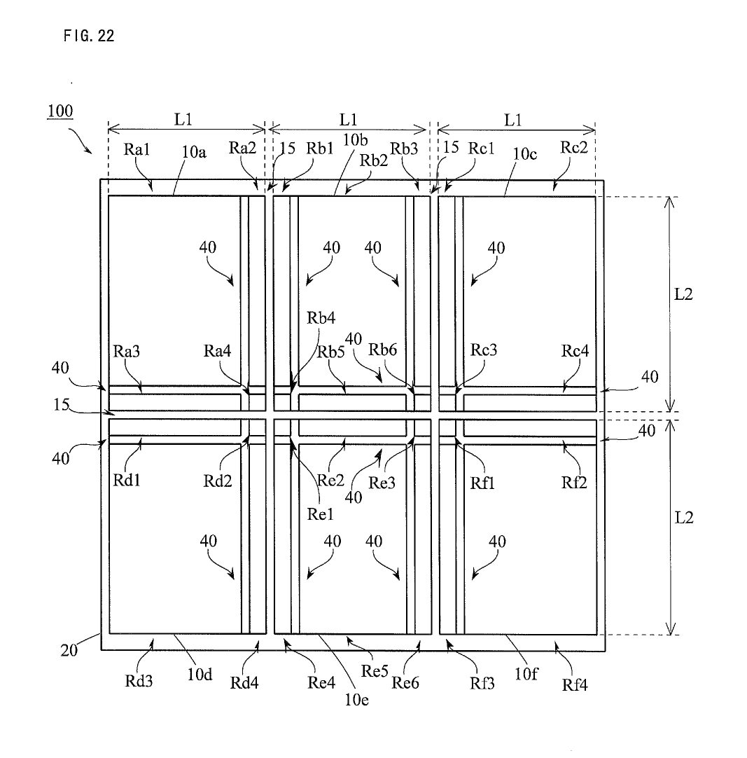

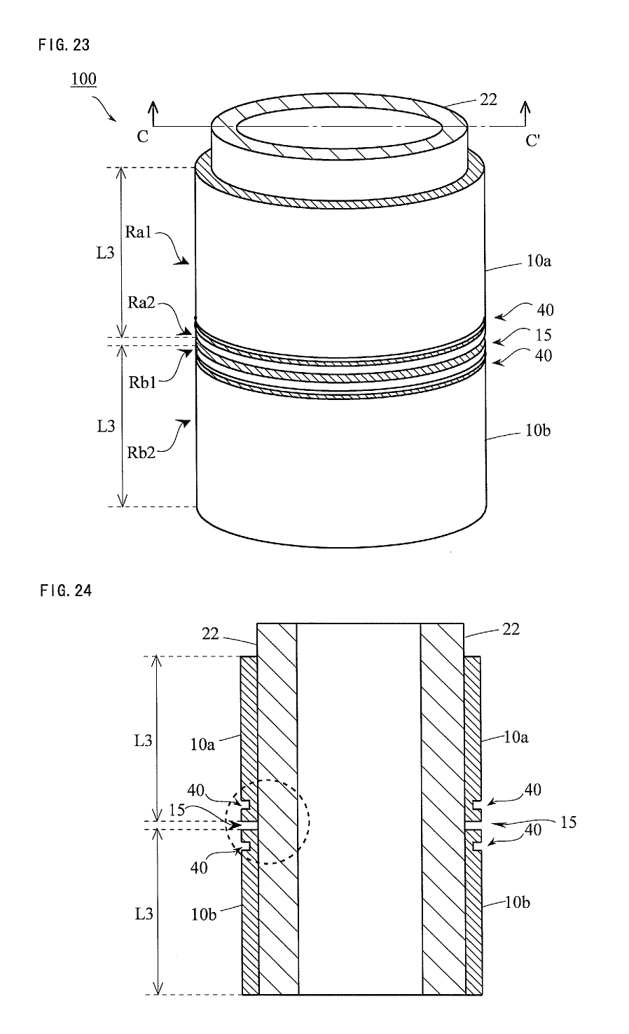

FIG. 20 is a plan view showing a configuration of the sputtering target 100 according to a sixth modified example of the present embodiment. The sputtering target 100 according to the present modified example is provided with six tabular target materials 10a to 10f (hereinafter, these are each referred to as “target material 10” when not distinguished) made of the same material (IGZO). Hereinafter, in the present modified example, the target material 10a located on the upper left side in each of FIG. 20 and undermentioned FIGS. 22 and 23 may be referred to as “upper left-side target material 10a”, the target material 10b located on the upper center side may be referred to as “upper center-side target material 10b”, the target material 10c located on the upper right side may be referred to as “upper right-side target material 10c”, the target material 10d located on the lower left side may be referred to as “lower left-side target material 10d”, the target material 10e located on the lower center side may be referred to as “lower center-side target material 10e”, and the target material 10f located on the lower right side may be referred to as “lower right-side target material 10f”. It is to be noted that, while the example is shown in FIG. 20 where three target materials 10 are laterally arranged and two target materials 10 are longitudinally arranged, the number of target materials 10 in the present modified example is not restricted thereto.

In the sputtering target 100 according to the present modified example, there exist not only the joint 15 (hereinafter referred to as “longitudinally extending joint 15”) of the target materials 10 which are laterally adjacent to each other, but also the joint 15 (hereinafter referred to as “laterally extending joint 15”) of the target materials 10 which are longitudinally adjacent to each other.

In the present modified example, corresponding to one longitudinally extending joint 15, one groove 40 having the length L2 and the depth D1 is provided on each of one surface and the other surface of the mutually adjacent target materials 10 forming the longitudinally extending joint 15, in a manner parallel to the longitudinally extending joint 15. That is, the grooves 40 split the surface of the upper left-side target material 10a into regions Ra1 and Ra2, the surface of the upper center-side target material 10b into regions Rb1, Rb2 and Rb3, the surface of the upper right-side target material 10c into regions Rc1 and Rc2, the surface of the lower left-side target material 10d into regions Rd1 and Rd2, the surface of the lower center-side target material 10e into regions Re1, Re2 and Re3, and the surface of the lower right-side target material 10f into regions Rf1 and Rf2.

More specifically, corresponding to the joint 15 formed by the upper left-side target material 10a and the upper center-side target material 10b, one groove 40 is provided in the left-side vicinity of this joint 15 on the surface of the upper left-side target material 10a, and one groove 40 is provided in the right-side vicinity of this joint 15 on the surface of the upper center-side target material 10b. Further, corresponding to the joint 15 formed by the upper center-side target material 10b and the upper right-side target material 10c, one groove 40 is provided in the left-side vicinity of this joint 15 on the surface of the upper center-side target material 10b, and one groove 40 is provided in the right-side vicinity of this joint 15 on the surface of the upper right-side target material 10c. Moreover, corresponding to the joint 15 formed by the lower left-side target material 10d and the lower center-side target material 10e, one groove 40 is provided in the left-side vicinity of this joint 15 on the surface of the lower left-side target material 10d, and one groove 40 is provided in the right-side vicinity of this joint 15 on the surface of the lower center-side target material 10e. Furthermore, corresponding to the joint 15 formed by the lower center-side target material 10e and the lower right-side target material 10f, one groove 40 is provided in the left-side vicinity of this joint 15 on the surface of the lower center-side target material 10e, and one groove 40 is provided in the right-side vicinity of this joint 15 on the surface of the lower right-side target material 10f.

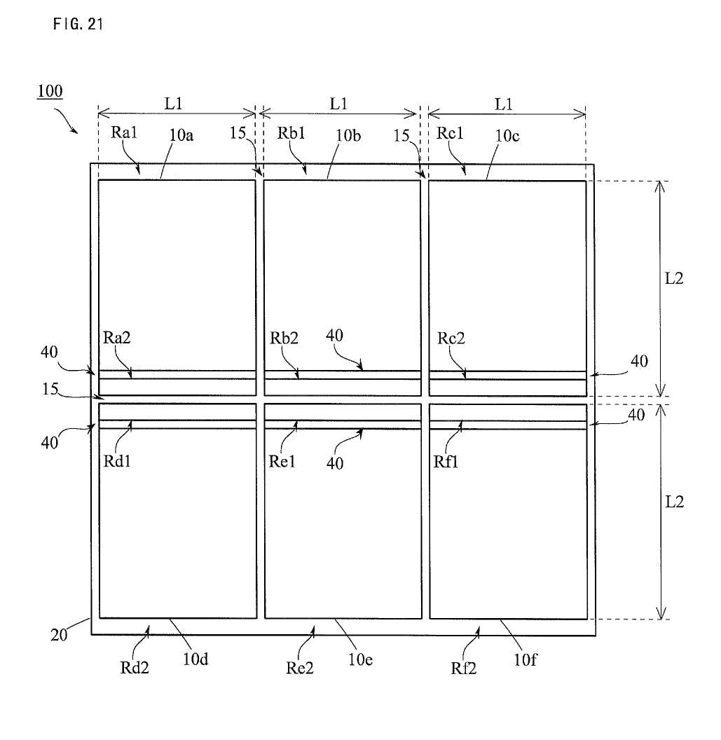

In addition, it may be configured that the groove 40 having the length L1 and the depth D1 is provided parallel to the laterally extending joint 15, as shown in FIG. 21. In this configuration, the grooves 40 split the surface of the upper left-side target material 10a into regions Ra1 and Ra2, the surface of the upper center-side target material 10b into regions Rb1 and Rb2, the surface of the upper right-side target material 10c into regions Rc1 and Rc2, the surface of the lower left-side target material 10d into regions Rd1 and Rd2, the surface of the lower center-side target material 10e into regions Re1 and Re2, and the surface of the lower right-side target material 10f into regions Rf1 and Rf2.

More specifically, corresponding to the joint 15 formed by the upper left-side target material 10a and the lower left-side target material 10d, one groove 40 is provided in the upper-side vicinity of this joint 15 on the surface of the upper left-side target material 10a, and one groove 40 is provided in the lower-side vicinity of this joint 15 on the surface of the lower left-side target material 10d. Further, corresponding to the joint 15 formed by the upper center-side target material 10b and the lower center-side target material 10e, one groove 40 is provided in the upper-side vicinity of this joint 15 on the surface of the upper center-side target material 10b, and one groove 40 is provided in the lower-side vicinity of this joint 15 on the surface of the lower center-side target material 10e. Moreover, corresponding to the joint 15 formed by the upper right-side target material 10c and the lower right-side target material 10f, one groove 40 is provided in the upper-side vicinity of this joint 15 on the surface of the upper right-side target material 10c, and one groove 40 is provided in the lower-side vicinity of this joint 15 on the surface of the lower right-side target material 10f.

Furthermore, the configuration shown in FIG. 20 may be combined with the configuration shown in FIG. 21, as shown in FIG. 22. That is, it may be configured that the groove 40 having the length L2 and the depth D1 is provided parallel to the longitudinally extending joint 15 and in the vicinity of this longitudinally extending joint 15, while the groove 40 having the length L1 and the depth D1 is provided parallel to the laterally extending joint 15 and in the vicinity of this laterally extending joint 15. In this configuration, the grooves 40 split the surface of the upper left-side target material 10a into regions Ra1, Ra2, Ra3 and Ra4, the surface of the upper center-side target material 10b into regions Rb1, Rb2, Rb3, Rb4, Rb5 and Rb6, the surface of the upper right-side target material 10c into regions Rc1, Rc2, Rc3 and Rc4, the surface of the lower left-side target material 10d into regions Rd1, Rd2, Rd3 and Rd4, the surface of the lower center-side target material 10e into regions Re1, Re2, Re3, Re4, Re5 and Re6, and the surface of the lower right-side target material 10f into regions Rf1, Rf2, Rf3 and Rf4.

According to the present modified example, the electric-field concentration which occurs in the joint 15 can be alleviated in a sputtering target preferable for applications to a large-sized display panel. In addition, with the configuration shown in FIG. 22, the electric-field concentration which occurs in the joint 15 can be alleviated still more than in the configuration shown in FIG. 20 or 21.

### 2. Second Embodiment

### 2.1 Configuration of Sputtering Target

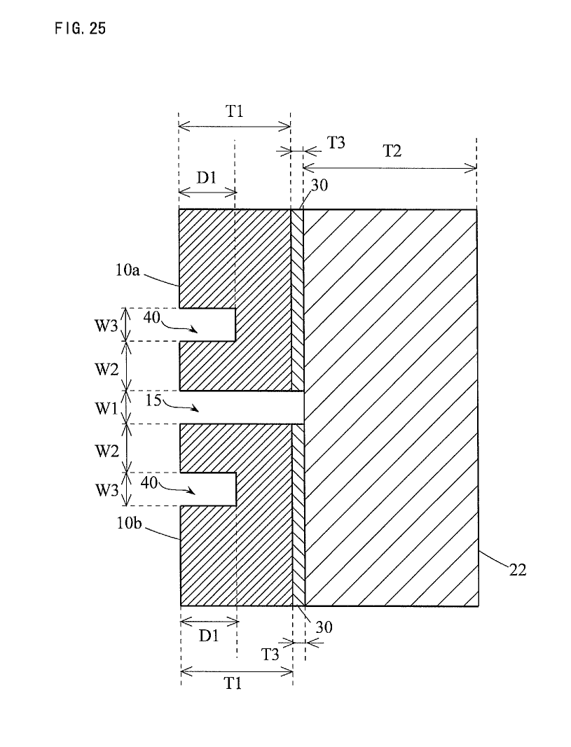

A configuration of a sputtering target according to a second embodiment of the present invention will be described with reference to FIGS. 23 to 25. It should be noted that, among constitutional elements in the present embodiment, the same element as that of the sputtering target 100 according to the first embodiment is provided with the same reference numeral, and a description thereof is omitted. FIG. 23 is a perspective view showing a configuration of the sputtering target 100 according to the present embodiment. FIG. 24 is a sectional view of the sputtering target 100 taken along C-C′ line shown in FIG. 23. FIG. 25 is a view obtained by enlarging a part (portion circled by a broken line) of the sectional view according to FIG. 24.

The sputtering target 100 according to the present embodiment is configured of two cylindrical sputtering target materials 10a and 10b (hereinafter, these are each referred to as “sputtering target material 10” when not distinguished) made of the same material (IGZO) and a backing tube 22 as a cylindrical support material, in place of three tabular sputtering target materials 10a to 10c and the backing plate 20. That is, the sputtering target 100 according to the present embodiment is a split sputtering target configured of the two cylindrical target materials 10a and 10b made of the same material (IGZO), the backing tube 22 and the bonding material 30. Hereinafter, in the present embodiment, the target material 10a located on the upper side in FIG. 23 or 24 may be referred to as “upper-side target material 10a”, and the target material 10b located on the lower side may be referred to as “lower-side target material 10b”. Here, an outer diameter and an inner diameter of each target material 10 are respectively larger than an outer diameter and an inner diameter of the backing plate 20. It is to be noted that, while the example is shown in FIGS. 23 and 24 where two target materials 10 are longitudinally arranged alongside, the present invention is not restricted thereto. The number of target materials 10 in the present embodiment is not restricted thereto.

The width W1 of the joint 15 in the present embodiment is sufficiently smaller than a height (longitudinal height) L3 of the target material 10 in FIG. 23. As shown in FIG. 25, the joint 15 is formed perpendicularly to the surface of the backing tube 22, but this is not restrictive. For example, the joint 15 may be formed in the step shape, the inclined shape, or the like, as described above.

The groove 40 is provided in a circumferential direction of the cylindrical target material 10. More specifically, the groove 40 having the depth D1 and the same length as a circumference of the target material 10 is provided parallel to the joint 15 in the vicinity of the joint 15 (position with the distance W2 from the joint 15). Here, the distance W2 between the joint 15 and the groove 40 is sufficiently smaller than the height L3 of the target material 10.

Moreover, corresponding to one joint 15, one groove 40 is provided on each of one surface and the other surface of the mutually adjacent target materials 10 forming this joint 15. That is, the grooves 40 split the surface of the upper-side target material 10a into regions Ra1 and Ra2, and the surface of the lower-side target material 10b into regions Rb1 and Rb2. More specifically, corresponding to the joint 15 formed by the upper-side target material 10a and the lower-side target material 10b, one groove 40 is provided in the upper-side vicinity of this joint 15 on the surface of the upper-side target material 10a, and one groove 40 is provided in the lower-side vicinity of this joint 15 on the surface of the lower-side target material 10b.

2.2 Method for Manufacturing Sputtering Target

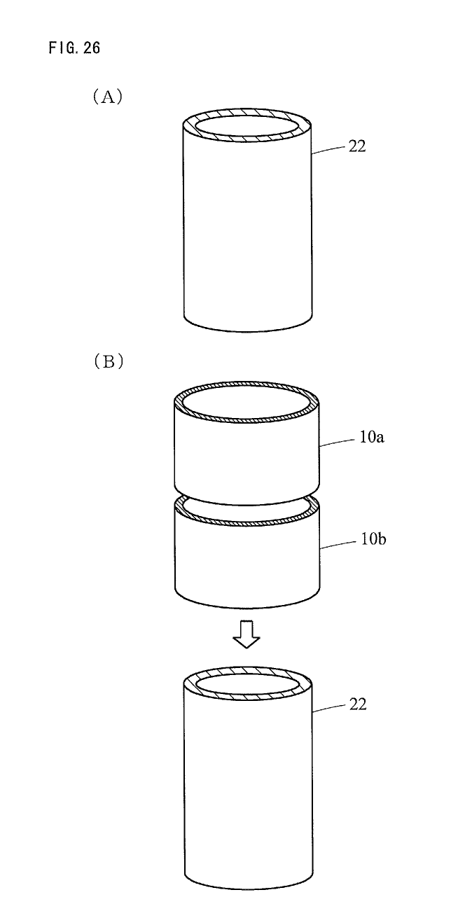

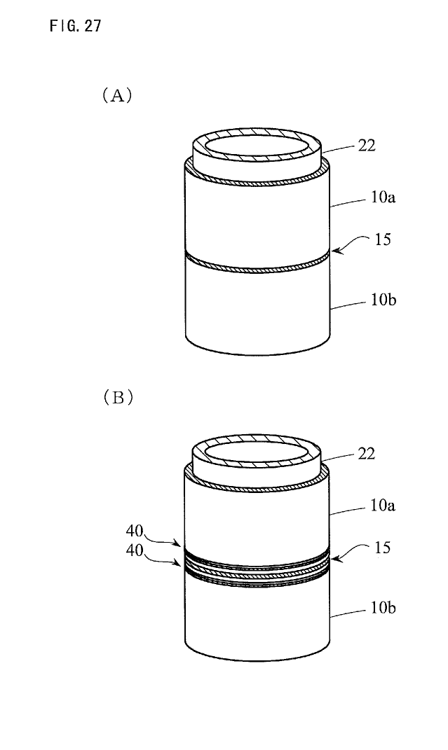

A method for manufacturing the sputtering target 100 according to the present embodiment will be described with reference to FIGS. 26(A) and 26(B) and FIGS. 27(A) and 27(B).

First, the target materials 10a and 10b on a cylinder which are made of IGZO are set into the cylindrical backing tube 22 (FIG. 26(A)) made of Cu or the like (FIG. 26(B)). At this time, the target materials 10a and 10b are desirably bonded to each other with a tape (e.g., insulating tape). Next, the melt bonding material 30 made of In or the like is injected into between the two target materials 10 and the backing tube 22. Subsequently, this insulating tape is peeled off, and the bonding material 30 in the joint 15 is raked out. It is to be noted that this insulating tape may not be peeled off.

Subsequently, the bonding material 30 is cooled, thereby to be solidified. Hence two target materials 10 are bonded to the backing tube 22 via the bonding material 30 (FIG. 27(A)). At this time, the joint 15 having the width W1 is formed. This width W1 can be accurately set by previously bonding the target materials 10a and 10b to each other by use of the insulating tape as described above.

Subsequently, using a disk grinder or the like, the groove 40 having the depth D1 is formed parallel to the joint 15 in a position with the distances W2 from the joint 15 on the surface of each target material 10 on the surface of each target material 10 (FIG. 27(B)). At this time, the surface of the upper-side target material 10a is split into regions Ra1 and Ra2, and the surface of the lower-side target material 10b is split into regions Rb1 and Rb2. It is to be noted that, the groove 40 can be uniformly formed when it is formed by fixing the backing tube 22 to a predetermined support stage while fixing the disk grinder so as to prevent displacement of a forming position of the groove 40, and rotating the backing tube 22 and the target material 10 which are bonded to each other by the bonding material 30. It should be noted that the groove 40 is formed not restrictively by grinding with a disk grinder or the like, but may be formed by lathing with a lathe or the like, or fusing with a laser or the like. Moreover, prior to bonding of the each target material 10 to the backing tube 22, the groove 40 may be formed on the surface of each target material 10, and thereafter, each target material 10 provided with the groove 40 may be bonded to the backing tube 22.

By the above method, the sputtering target 100 according to the present embodiment is manufactured.

### 2.3. Effects

According to the present embodiment, similar effects to those of the first embodiment can be exerted in the case of using the cylindrical target material 10.

### 3. Others

The sputtering target 100 according to the present invention can be applied not only to formation of a semiconductor film, but also to formation of a conductive film, and the like.

The bottom gate TFT having an etching stopper structure is described as the example in the first embodiment, but this is not restrictive. For example, a TFT having a channel etch structure, a top gate TFT, or the like may be used.

Also to the cylindrical sputtering target 100 according to the second embodiment, it is possible to apply the configuration of providing the groove 40 only on one side of the joint 15 as in the first modified example of the first embodiment, the configuration of making the depth D1 of the groove 40 larger as in the second modified example, the configuration of providing a large number of grooves 40 as in the third modified example, the configuration of performing chamfering as in the fourth modified example, and the configuration of providing the groove 40 on the center of the target material 10 as in the fifth modified example.

The cylindrical support material (backing tube 22) is used in the second embodiment, but in place of this, a columnar support material may be used.

While the present invention is described in each of the embodiments and the modified examples, the present invention is not restricted thereto. The present invention can variously be modified and implemented within the scope not departing from its spirit.

As thus described, according to the present invention, it is possible to provide a sputtering target capable of obtaining a semiconductor film with favorable characteristics. Further, according to the present invention, it is possible to provide a method for manufacturing a sputtering target capable of obtaining a film having favorable characteristics. Moreover, according to the present invention, it is possible to provide a method for manufacturing a thin-film transistor using a sputtering target capable of obtaining a semiconductor film having favorable characteristics.

The present invention can be applied to a sputtering target used for forming a semiconductor film and the like.

### DESCRIPTION OF REFERENCE CHARACTERS

10(10a-10f): target material
15: joint
20: backing plate (support material)
22: backing tube (support material)
30: bonding material
40: groove
100, 190: sputtering target
200, 290: TFT (thin-film transistor)
240: channel layer
Ra1-Ra4, Rb1-Rb6, Rc1-Rc4, Rd1-Rd4, Re1-Re6, Rf1-Rf4: region

1. A sputtering target, comprising:
a plurality of target materials made of an identical material;
a support material that supports the plurality of target materials; and
a bonding material that bonds the plurality of target materials and the support material, wherein
a surface of at least one of the mutually adjacent target materials is provided with a groove that splits the surface into two or more regions.

2. The sputtering target according to claim 1, wherein each target material is made of a semiconductor.

3. The sputtering target according to claim 2, wherein said semiconductor is an oxide semiconductor.

4. The sputtering target according to claim 3, wherein the oxide semiconductor mainly contains indium, gallium, zinc and oxygen.

5. The sputtering target according to claim 3, wherein the oxide semiconductor contains at least one of indium, gallium, zinc, copper, silicon, tin, aluminum, calcium, germanium and lead.

6. The sputtering target according to claim 2, wherein the groove is provided parallel to the joint between the mutually adjacent target materials.

7. The sputtering target according to claim 6, wherein the groove is provided in the vicinity of the joint.

8. The sputtering target according to claim 7, wherein, corresponding to the joint, at least one groove is provided on each of one surface and the other surface of the mutually adjacent target materials.

9. The sputtering target according to claim 8, wherein, corresponding to the joint, a plurality of grooves are provided on each of one surface and the other surface of the mutually adjacent target materials.

10. The sputtering target according to claim 7, wherein, corresponding to the joint, one groove is provided on one surface of the mutually adjacent target materials.

11. The sputtering target according to claim 2, wherein a depth of the groove is one-half or larger of a thickness of the target material provided with the groove, and smaller than the thickness of the target material provided with the groove

12. The sputtering target according to claim 2, wherein edge portions of each target material which correspond to the groove and the joint are chamfered.

13. The sputtering target according to claim 2, wherein
the support material is formed in a tabular shape, and
each target material is formed in a tabular shape.

14. The sputtering target according to claim 2, wherein
the support material is formed in a cylindrical shape or in a columnar shape, and
each target material is formed in the cylindrical shape.

15. A method for manufacturing a thin-film transistor, comprising a step of:
forming a channel layer by sputtering the sputtering target according to claim 2.

16. A method for manufacturing a sputtering target having a plurality of target materials made of an identical material, a support material that supports the plurality of target materials, and a bonding material that joins the plurality of target materials and the support material, the method comprising a step of:
forming a groove on the surface of at least one of the mutually adjacent target materials, the groove splitting the surface into two or more regions.
